(19) United States
(12) Patent Application Publication
(10) Pub. No.: US 2026/0271691 A1
(43) Pub. Date: Sep. 10, 2026

(54) METHOD FOR FILLING COBALT INTO THROUGH VIAS OF A SEMICONDUCTOR WAFER

(71) Applicant: City University of Hong Kong, Hong Kong (HK)

(72) Inventors: Yingxia LIU, Hong Kong (HK); Zishan XIONG, Hong Kong (HK)

(21) Appl. No.: 19/385,149

(22) Filed: Nov. 11, 2025

Related U.S. Application Data
(60) Provisional application No. 63/768,196, filed on Mar. 7, 2025.

(51) Int. Cl. H01L 21/768; C25D 3/12; C25D 5/02; C25D 7/12; H01L 21/288

(52) U.S. Cl. CPC H10W 20/057; C25D 3/12; C25D 5/02; C25D 7/12; H10P 14/47; H10W 20/023

(57) ABSTRACT

A method for filling cobalt into through vias of a semiconductor wafer is disclosed. The method comprises preparing a cobalt-based electroplating solution, performing wetting treatment on the through vias, and electroplating cobalt into the wetting-treated vias. The wetting treatment includes immersing the wafer in an organic solvent, immersing the wafer in deionized water, and placing the wafer in a vacuum container containing the electroplating solution to enhance wettability by releasing trapped air from the through-silicon via (TSV) holes. Incorporating a leveling agent and an inhibitor in the electroplating solution enables void-free filling of high aspect ratio TSVs. The process can be further tailored with electrolyte additives to improve trench filling, broaden the process window, and lower manufacturing costs. Compared with conventional CVD and PVD methods, the disclosed method provides improved filling performance and enhanced industrial applicability.

### CROSS-REFERENCE TO RELATED APPLICATIONS

The present application claims priority from the U.S. Provisional Patent Application No. 63/768,196 filed Mar. 7, 2025, and the disclosure of which is incorporated herein by reference in its entirety.

### FIELD OF THE INVENTION

The present invention belongs to the technical field of semiconductor packaging processes for integrated circuits and specifically relates to method for filling cobalt into through vias of a semiconductor wafer.

### BACKGROUND OF THE INVENTION

With the occurrence of the big data era, the demand for chip processing power has gradually increased, necessitating a rise in transistor density per unit area to enhance computing power. However, as transistor size decreases and the number of stack layers increases, it becomes necessary to pass through multiple, such as 10 to 20, stack layers to provide power and data signals to the transistors beneath, resulting in a resource crowding problem in the line layer where interconnect and power lines coexist.

In order to solve the resource crowding problem between the signal network and the power supply network, Belgium IMEC proposed backside power delivery network (BSPDN), which can increase density of transistors per unit area while avoiding signal interference, reducing wiring congestion at the back end of the line, and providing a power performance advantage, thereby improving chip reliability. At the same time, Samsung stated that when compared to the 2 nm process using traditional front side power delivery network (FSPDN) power supply method, the SF2Z node 2 nm process using BSPDN can significantly improve the circuit voltage drop problem, reduce about 17% of the chip area, increase energy efficiency by about 15%, and improve performance by about 8%. Backside-powered technology, on the other hand, necessitates silicon beneath transistors being thinned to 500 nm or less. It is powered by micron-sized vias running vertically to the back of the silicon through nanometer-diameter through silicon vias (nanoTSV), which connect the back of the silicon to the underside of the buried power rails.

When the line width of the interconnect line filled with copper metal in a conventional silicon through-hole (TSV) is reduced to 40 nm, the electrons inside the copper are subjected to strong grain boundary scattering and interface scattering because the copper's electron free range is approximately 39 nm, and the eigenvalue is less than the electron mean free range. If the size of the filler copper is reduced without reducing the size of the functional layer, the interconnect would be susceptible to interconnect problem produced by a rapid increase in the resistance of the copper line's surface and the internal grain boundaries. The rapid rise in the surface and internal grain boundary resistance of the copper lines causes the total resistance of the interconnects to increase. Thus, selecting a metal with a lower electron mean free range prevents the resistivity increase.

Cobalt, with an electron mean free range of just 10 nm, will have a lower current resistance than copper. Cobalt can be utilized as a barrier or adhesion layer, and no functional layer is required when used as a TSV filler material, increasing interconnect metal conductivity. The use of cobalt filling for TSVs with a diameter of 100 nm to 1 μm has significant advantages and is suitable for interconnect topologies below 7 nm.

A typical TSV process begins with the production of TSV holes and the deposition of functional layers (insulating, diffusion barrier, and seed layers), which are then followed by the deposition of conductive materials to fill the holes. The most common metal filling technologies for TSVs are chemical vapor deposition (CVD), physical vapor deposition (PVD), and electroplating. Because CVD deposition requires complex and expensive precursors, and PVD deposition typically results in voids and limited step coverage, electroplating is a more common method for filling metals into TSV structures in industry. At the same time, the electroplating process has the advantages of low cost, high filling rate, and so on, which has a broad industrial promotion prospect.

The high aspect ratio of small-sized TSVs poses challenges for complete electrolyte filling due to surface tension effects between the electrolyte and air within the blind vias. This tension hinders the electrolyte's ability to fully penetrate and fill the vias, potentially leading to voids at the bottom and limiting both the filled aspect ratio and the quality of the deposition In conventional electroplating filling process, because of the increased mass transfer conditions and electric field at the top of the through-hole, cobalt tends to concentrate more rapidly at the top than at the bottom, resulting in a voided structure. Moreover, when the current density increases, the possibility of void formation equally escalates, owing to a heightened concentration of current at the top of the hole and an augmented limitation on mass transfer at the bottom. When the TSV diameter is 100 nm to 1 μm, the depth-to-width ratio increases, hollow defects in the interior of the TSV after plating are likely to occur. Additionally, additives in the plating solution can cause cobalt deposition, thereby affect plating quality.

### SUMMARY OF THE INVENTION

The present invention aims to solve the technical problem of hollow defects in electroplating cobalt fillings for small-sized TSVs, in particular with diameters of 100 nm to 1 μm, which are required for back-powered technologies.

According to the present invention, a method for filling cobalt into through vias of a semiconductor wafer is provided. The method comprises: preparing a cobalt-based electroplating solution; performing wetting treatment on the through vias of the semiconductor wafer to obtain a wetting-treated wafer with wetting-treated through vias; and filling cobalt into the wetting-treated through vias of the wetting-treated wafer by performing electroplating treatment with the prepared cobalt-based electroplating solution. The wetting treatment is performed by: immersing the semiconductor wafer in an organic solvent to obtain an organic solvent-treated wafer; immersing the semiconductor wafer in deionized water to obtain a deionized water-treated wafer; and putting the deionized water-treated wafer in a vacuum container containing the prepared cobalt-based electroplating solution to obtain the wetting-treated wafer.

Preferably, the cobalt-based electroplating solution is prepared by: dissolving and mixing a cobalt-based main salt and a stabilizer into deionized water to obtain a first solution; dissolving a buffer into the first solution to obtain a second solution; successively adding a grain refiner, a surfactant, a levelling agent and an inhibitor into the second solution to obtain a third solution; fixing the third solution to a required amount with deionized water; and adjusting the pH value of the third solution using an acid and/or alkaline to obtain the cobalt-based electroplating solution.

Preferably, the cobalt-based main salt is a cobalt sulfate heptahydrate.

Preferably, the stabilizer is a methanesulfonic acid, a sodium methanesulfonate, a citric acid, a sodium citrate, an ethylenediaminetetraacetic acid (EDTA) or any combinations thereof.

Preferably, the buffer is a boric acid, a sodium borate, a phosphoric acid, a sodium phosphate, an acetic acid and a sodium acetate or any combinations thereof.

Preferably, the grain refiner is a 1,3,5-naphthalene trisulfonic acid, a thiophene-2-sulfonic acid, a bis(phenylsulfonyl)imide, a N-propenylpyridinium chloride or any combinations thereof.

Preferably, the surfactant is a dipentyl sulfosuccinate sodium salt, a sodium polyoxyethylene alkyl phenol ether sulfate, and a lauryl ether sulfate or any combinations thereof.

Preferably, the levelling agent is a dimethylglyoxime.

Preferably, the inhibitor is a mercaptobenzimidazole sulfonic acid, a polyethyleneimine, a thiourea, a butanedione oxime, a 2-mercaptobenzimidazole benzenesulfinic acid, and an alkynyl-PEG4-amine or any combinations thereof.

Through performing wetting treatment in vacuum environment, air is allowed to escape from the TSV holes, bringing the TSV hole walls into touch with the plating solution and boosting wettability. Moreover, by incorporating levelling agent and inhibitor into the electroplating solution, a high depth-to-width ratio TSV filling can be obtained, producing a void-free structure in which cobalt completely fills the through-silicon via holes. Experimental results demonstrate that the pre-wetting treatment and suitable additive selection enabled cobalt TSV fillings with a diameter of 1 μm and aspect ratio of 10:1. Notably, the electroplating treatment of the present invention can be further tailored through the selection of suitable electrolyte additives to provide superior trench filling capability. This results in an expanded process window, improved filling performance compared to CVD and PVD methods, and reduced manufacturing cost, thereby enhancing the potential for industrial adoption.

### BRIEF DESCRIPTION OF THE DRAWINGS

Embodiments of the invention are described in more details hereinafter with reference to the drawings, in which:

FIG. 1 shows a flowchart of a method for filling cobalt into through vias of a semiconductor wafer in accordance with one embodiment of the present invention;

FIG. 2 shows a schematic diagram of the TSV structure;

FIG. 3A shows Focused Ion Beam Scanning Electron Microscope (FIB-SEM) images of TSV filling results without acetone immersion treatment; FIG. 3B shows FIB-SEM images of TSV filling results after acetone immersion treatment;

FIG. 4A shows CV curves of various concentrations; FIG. 4B shows Q/Q0 as a function of DMG and AP4A concentration; FIG. 4C shows Potential change obtained in the chronopotentiometry tests with increasing concentration of DMG and AP4A, FIG. 4D shows Impact of different rotation speeds (100/1000 rpm) in chronopotentiometry tests with increasing concentration of DMG and AP4A;

FIG. 5A shows XRD patterns of cobalt films deposited; FIGS. 5B to 5E show XPS survey image of cobalt film surfaces without Additives, with 80 mg/L DMG, with 160 mg/L DMG and with 5 ppm AP4A respectively; FIGS. 5F to 5I show XPS High-resolution spectra image and fitted curves of cobalt film surfaces without Additives, with 80 mg/L DMG, with 160 mg/L DMG and with 5 ppm AP4A respectively;

FIGS. 6A to 6D show AFM images of cobalt film surfaces without Additives, with 80 mg/L DMG, with 160 mg/L DMG, and with 5 ppm AP4A, respectively;

FIGS. 7A to 7D show SEM images of cobalt film surfaces without Additives, with 80 mg/L DMG, with 160 mg/L DMG, and with 5 ppm AP4A, respectively;

FIG. 8 shows Cross-sectional FIB-SEM views of cobalt super filling after electrodeposition with 160 mg/L DMG; insets (a)-(c) show FIB-SEM images of top, middle, and bottom regions of a single TSV-filled section respectively;

FIG. 9 shows Cross-sectional FIB-SEM views of cobalt super filling after electrodeposition with 5 ppm AP4A; insets (a)-(c) show FIB-SEM images of top, middle, and bottom regions of a single TSV-filled section;

FIGS. 10A and 10B show 2D view images of cobalt super-filling after electrodeposition with 160 mg/L DMG; FIGS. 10C and 10D show 3D X-ray CT images of cobalt super-filling after electrodeposition with 160 mg/L DMG;

FIG. 11A shows scheme for bottom-up super filling of cobalt electrodeposition without additive, FIG. 11B shows schematic of AP4A structural formula, FIG. 11C shows schematic of DMG structural formula, FIG. 11D shows scheme for bottom-up super filling of cobalt electrodeposition with DMG.

### DETAILED DESCRIPTION

In the following description, details of the present invention are set forth as preferred embodiments. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

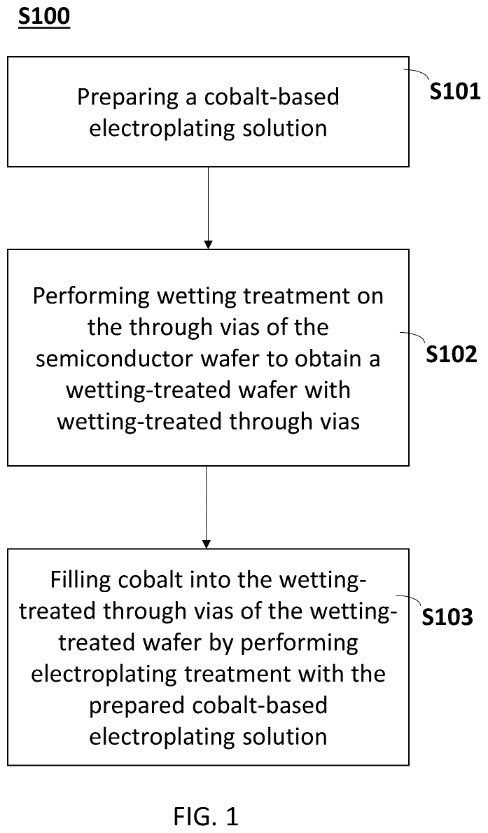

FIG. 1 illustrate a method S100 for filling cobalt into through vias of a semiconductor wafer in accordance with one embodiment of the present invention. As shown, the method S100 comprises the following steps:
S101: preparing a cobalt-based electroplating solution;
S102: performing wetting treatment on the through vias of the semiconductor wafer to obtain a wetting-treated wafer with wetting-treated through vias; and
S103: filling cobalt into the wetting-treated through vias of the wetting-treated wafer by performing electroplating treatment with the prepared cobalt-based electroplating solution.

In some embodiments, the method S100 further comprises preprocessing the semiconductor wafer such that each of the through vias has one or more functional layers such as insulating layer, diffusion barrier layer, and seed layer for electroplating.

In some embodiments, in the step S101, the cobalt-based electroplating solution is prepared by: dissolving and mixing a cobalt-based main salt and a stabilizer into deionized water to obtain a first solution; dissolving a buffer into the first solution to obtain a second solution; successively adding a grain refiner, a surfactant, a levelling agent and an inhibitor into the second solution to obtain a third solution; fixing the third solution to a required amount with deionized water; and adjusting pH value of the third solution using an acid and/or alkaline to obtain the cobalt-based electroplating solution.

Preferably, the cobalt-based main salt may be a cobalt sulfate heptahydrate. The stabilizer may be methanesulfonic acid, sodium methanesulfonate, citric acid, sodium citrate, ethylenediaminetetraacetic acid (EDTA) or any combinations thereof. The buffer may be boric acid, sodium borate, phosphoric acid, sodium phosphate, acetic acid, sodium acetate or any combinations thereof. The grain refiner is 1,3,5-naphthalene trisulfonic acid, thiophene-2-sulfonic acid, bis(phenylsulfonyl)imide, N-propenylpyridinium chloride or any combinations thereof. The surfactant is dipentyl sulfosuccinate sodium salt, sodium polyoxyethylene alkyl phenol ether sulfate, lauryl ether sulfate or any combinations thereof. The levelling agent is a Dimethylglyoxime or 2,3-Butanedione Dioxime (Disperse Blue (Dye) 35). The inhibitor is mercaptobenzimidazole sulfonic acid, polyethyleneimine, thiourea, butanedione oxime, 2-mercaptobenzimidazole benzenesulfinic acid, alkynyl-PEG4-amine or any combinations thereof.

In one embodiment, cobalt-based main salt may be a cobalt sulfate heptahydrate; the stabilizer is sodium citrate; the buffer is sodium borate; the grain refiner is 1,3,5-naphthalene trisulfonic acid; the surfactant is sodium polyoxyethylene alkyl phenol ether sulfate; the levelling agent is a dimethylglyoxime, the inhibitor is butanedione oxime. The sodium citrate and the cobalt sulfate heptahydrate have a weight ratio equal to 3:8; the sodium borate and the cobalt sulfate heptahydrate have a weight ratio equal to 5:16; the 1,3,5-naphthalene trisulfonic acid and the cobalt sulfate heptahydrate have a weight ratio equal to 1:800; the sodium polyoxyethylene alkyl phenol ether sulfate and the cobalt sulfate heptahydrate have a weight ratio equal to 1:200; the dimethylglyoxime and the cobalt sulfate heptahydrate have a weight ratio equal to 1:320; and the butanedione oxime and the cobalt sulfate heptahydrate have a weight ratio equal to 3:800.

In some embodiments, in the step S102, the wetting treatment is performed by: immersing the semiconductor wafer in an organic solvent, such as ethanol or acetone, to obtain an organic solvent-treated wafer; immersing the semiconductor wafer in deionized water to obtain a deionized water-treated wafer; and putting the deionized water-treated wafer in a vacuum container containing the prepared cobalt-based electroplating solution to obtain the wetting-treated wafer.

More specifically, to pre-wet a silicon wafer with TSV functional layer, vacuum treatment or liquid wetting techniques are utilized to ensure electroplating solution enters the 100 nm-1 μm TSV holes. The good wettability of a selected organic solvent firstly enables the organic solvent to fully enter into the TSV holes; and because the selected organic solvent and water are miscible in any proportion, deionized water replaces the organic solvent in the TSV holes, so that the subsequent plating solution can be further immersed into the TSV holes; and the vacuum treatment further helps the air to be discharged. The vacuum treatment allows air to escape from the TSV holes, bringing the TSV hole walls into touch with the plating solution and boosting wettability.

In some embodiments, in the step S103, the electroplating treatment is performed by: immersing the wetting-treated wafer in the prepared electroplating solution under the conditions of 0.8A/dm² electroplating current density and 65° C. plating temperature to fill cobalt in the TSV of the wafers.

More specifically, the inhibitor in the plating solution alters the distribution of electric field lines in the electroplating bath, thereby slowing the deposition of cobalt on the surface of the TSV and serving as a key additive for achieving “bottom-up” filling. The leveling agent, in contrast, readily adsorbs onto the surface of the TSV or at the pore openings, suppressing cobalt ion deposition at those regions and permitting cobalt ions at the bottom of the pore, where the concentration of leveling agent is lower, to continue to deposit and grow. By incorporating both additives into the plating solution, a high depth-to-width ratio TSV filling can be obtained, producing a void-free structure in which cobalt completely fills the through-silicon via holes. Notably, the electroplating treatment of the present invention can be further tailored through the selection of suitable electrolyte additives to provide superior trench filling capability. This results in an expanded process window, improved filling performance compared to CVD and PVD methods, and reduced manufacturing cost, thereby enhancing the potential for industrial adoption.

In one implementation example, electroplating cobalt filling into TSVs having diameter of 1 μm, depth of 10 μm and a spacing of 5 μm is performed. The main components of the electroplating include: main salt 5-20 g/L; stabilizer 1-50 g/L; Buffer 10-30 g/L; grain refiner 1-500 mg/L; surfactant 0.1-1 g/L; leveling agent 0.1-1 g/L; inhibitor 1-500 mg/L.

Preferably, the main salt of the plating solution is a cobalt sulfate heptahydrate acting as the raw material for the reaction. The stabilizer is one or more of: methanesulfonic acid, sodium methanesulfonate, citric acid, sodium citrate, ethylenediaminetetraacetic acid (EDTA). The buffer is one or more of: boric acid, sodium borate, phosphoric acid, sodium phosphate, acetic acid and sodium acetate. The grain refiner is one or more of: 1,3,5-naphthalene trisulfonic acid, thiophene-2-sulfonic acid, bis(phenylsulfonyl)imide, N-propenylpyridinium chloride. The surfactant is one or more of: dipentyl sulfosuccinate sodium salt, sodium polyoxyethylene alkyl phenol ether sulfate, and lauryl ether sulfate. The leveling agent is Disperse Blue (Dye) 35. The inhibitor is one or more of: mercaptobenzimidazole sulfonic acid, polyethyleneimine, thiourea, butanedione oxime, 2-mercaptobenzimidazole benzenesulfinic acid, and alkynyl-PEG4-amine.

The main conditions for performing the electroplating are: acidity pH 2-6; current density 0.1-3A/dm²; and temperature 20-70° C.

In the step of electroplating solution preparation, 80 g of cobalt sulfate heptahydrate and 30 g of sodium citrate are dissolved in 200 mL of deionized water and thoroughly mixed, then 25 g of sodium borate is added to dissolve. Following that, 0.1 g of 1,3,5-naphthalene trisulfonic acid, 0.4 g of sodium alkylphenol ether sulfate, and 0.25 g of disperse blue (dye) 35, 300 mg of oxime are added successively, agitated to dissolve uniformly, and the solution is fixed with deionized water to 1,000 mL. The pH value of the fixed solution is adjusted to 4.5 using sulfuric acid or sodium hydroxide to obtain a 1 L of cobalt sulfate electroplating solution.

In the step of wetting treatment, the TSV wafer with prepared functional layer is immersed in alcohol or acetone for 10 min, while the wafer is later immersed in deionized water for 10 min; finally, it is put into the vacuum flask containing the prepared electroplating solution for vacuuming, with a vacuum degree of 0.075 mPa, and the vacuuming time is 30 min.

In the step of electroplating, the wetting-treated wafers are immersed in the prepared electroplating solution to fill cobalt in the TSV of the wafers under the conditions of 0.8A/dm² electroplating current density 0.8A/dm² and 65° C. plating temperature. The wafers are dried at the end of plating.

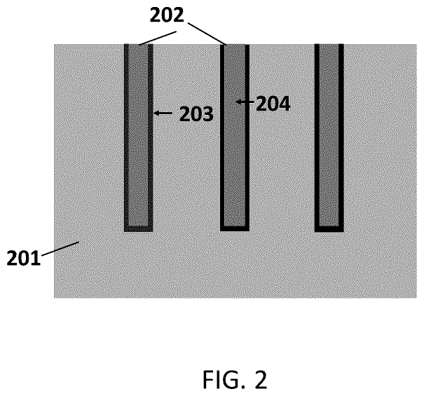

FIG. 2 shows a schematic diagram of the TSV structure 200 formed in a silicon substrate 201. The TSVs 202 have depositions of functional layers 203, including, but not limited to insulating, diffusion barrier, and seed layers, which are then followed by the electroplating of cobalt filling 204.

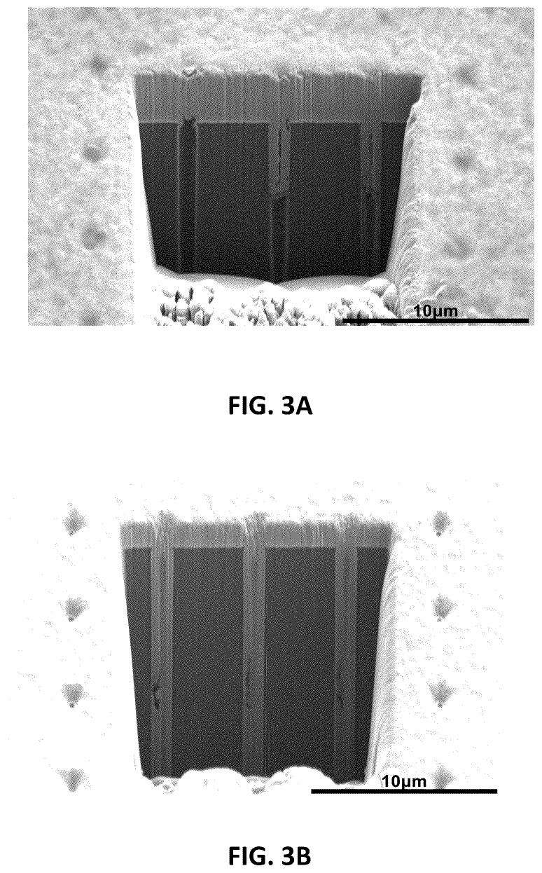

To demonstrate the technical effect of the present invention, electroplating filling was conducted on both the acetone-treated and non-acetone-treated TSV samples using electroplating solution without any additives. The electroplating filling FIB-SEM findings for non-acetone-immersed and acetone-immersed TSV samples are shown in FIG. 3A and FIG. 3B, respectively. Due to the lack of adequate wetting, the depth of filling of the TSVs without acetone immersion treatment is shallower than that of the TSVs with the alcohol wetting treatment, and there was also a failure filling that did not fill into the TSV holes. This demonstrates the strong necessity of acetone/ethanol immersion treatment in TSV filling.

The pre-wetting treatment, which includes absolute ethanol/acetone infiltration, deionized water washing, and a cobalt electrolyte bath, can make the plating solution smoothly enter the TSV. Meanwhile, the subsequent application of the vacuum wetting method can further expel the air inside the TSV holes to facilitate further wetting of the plating solution with the TSV hole walls. Based on the combination of these two wetting methods, it can further contribute to the filling of small-sized TSVs.

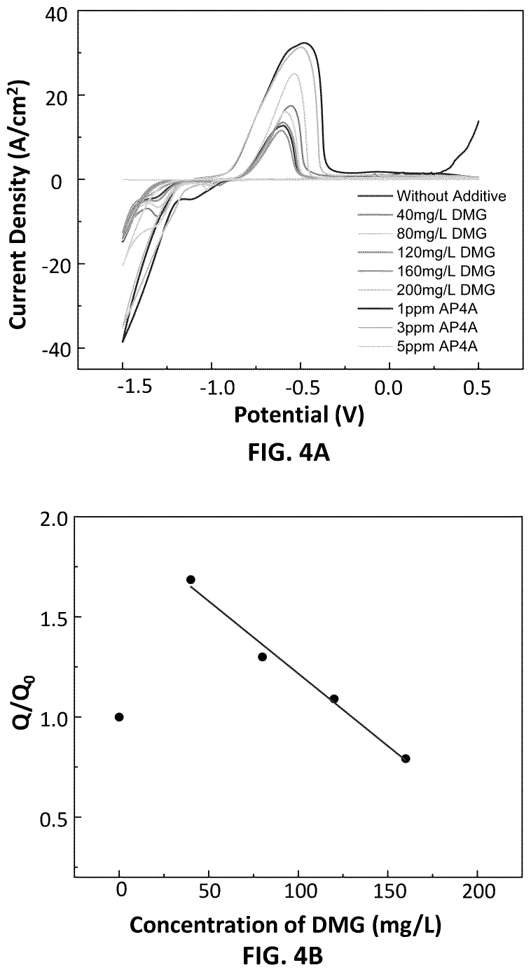

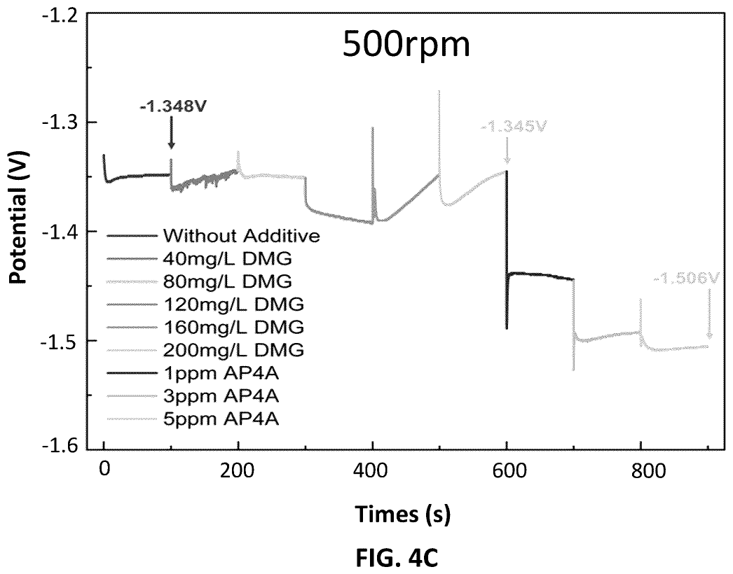

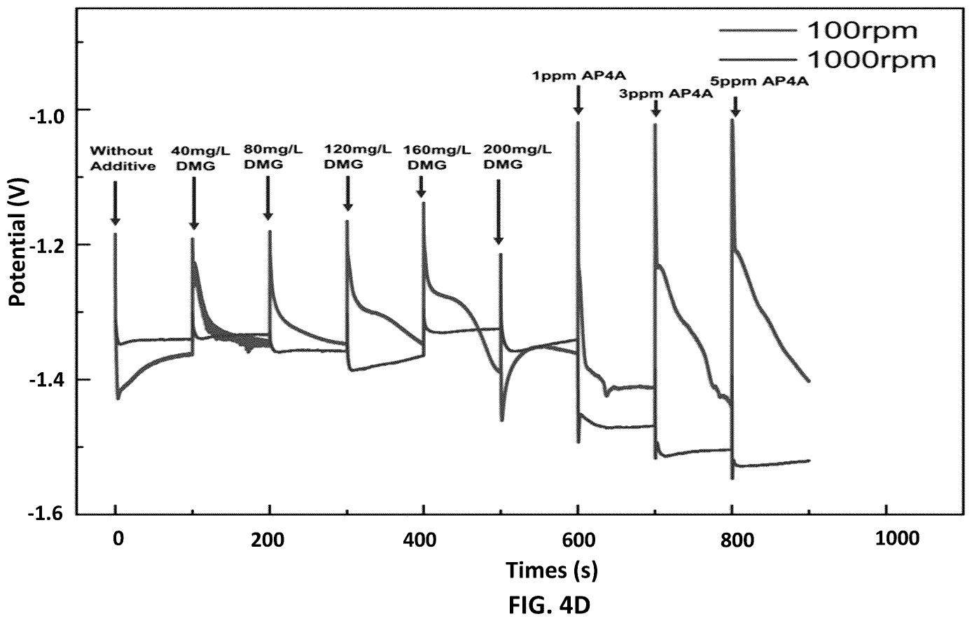

The electrochemical tests were designed to reveal the inhibitive behaviors of additives on cobalt electrodeposition (Table 1). And FIG. 4A illustrates the CV results obtained at different concentrations of DMG and AP4A. When the additional concentration of DMG is less than 160 mg/L, the CV curve steadily widens, indicating that increasing DMG enhances cobalt deposition. As the DMG concentration exceeds 160 mg/L, the CV curve slowly declines with increasing DMG concentration, signifying that DMG progressively inhibits cobalt deposition in the plating solution throughout this period. As AP4A concentration increases, the anodic stripping region in the CV curve decreases, indicating that it inhibits cobalt deposition. AP4A promotes the polarization of cobalt electrodeposition, as evidenced by a drop in cobalt deposition potential as concentration increases. Furthermore, when the concentration of AP4A increases, the cobalt deposition potential lowers, indicating that AP4A promotes the polarization of cobalt electrodeposition.

TABLE 1
Electrochemical Parameters

| | | Concentra- | Concentra- | Rotation |
|---|---|---|---|---|
| Test | Parameter | tion of DMG | tion of AP4A | Speed (rpm) |
| cyclic | −1.5 V- | 0-200 mg/L | 1-5 ppm | 500 |
| voltammetry | 0.5 V | | | |
| (CV) | | | | |
| chronopo- | 0.2ASD | 0-200 mg/L | 1-5 ppm | 100/500/ |
| tentiometry | | | | 1000 |

The inhibitory impact and saturation concentration of various DMG concentrations were examined by linear fitting using the cross-point approach (FIG. 4B). The integral value of the anodic dissolution peak of the CV curve was defined as Q0 in the absence of DMG and Q in the presence of DMG. Notably, the ratio of Q/Q0 was affected by the concentration of DMG. The values of Q/Q0 decreased significantly with increasing DMG concentrations, illustrating the inhibitory effect becoming increasingly obvious with the increase of DMG concentration. Additionally, the chronopotentiometry tests reveal the inhibitory effect of DMG and AP4A.

FIG. 4C illustrates potential transients observed during cobalt deposition. The addition of AP4A and DMG initially causes a transient polarization enhancement, followed by a gradual potential drop until stable polarization is achieved. With DMG, the cathodic potential slightly increases from −1.348 V (without additive) to −1.345 V at a concentration of 200 mg/L. As DMG concentration reaches 160 mg/L, the potential decreases, approaching saturation of the inhibitory effect, and then gradually increases with further concentration. Conversely, when DMG concentration exceeds 160 mg/L, the potential increases and the inhibitory effect is enhanced, consistent with cyclic voltammetry (CV) results. In comparison, AP4A significantly decreases the cathodic potential from −1.348 V to −1.506 V at 5 ppm. As AP4A concentration increases, the potential drops further, nearing saturation of inhibition, aligning with CV findings. Electrochemical tests indicate that AP4A functions effectively as an inhibitor. Additionally, potential transients on a rotating disk electrode exhibit strong and rapid suppression upon DMG injection.

Furthermore, the chronopotentiometry tests (FIG. 4D) were performed to simulate the top and bottom of the structures and predict the super-filling capacity with high and low rotation speeds, respectively. The potential at 100 rpm is higher than at 1000 rpm for the same concentration, implying a lower inhibitory effect. As a result, the deposition rate on the bottom should be greater than that on the surface, favoring bottom-up electrodeposition. Based on the electrochemical characterization presented above, both AP4A and DMG are considered to exhibit exceptional super-filling potential.

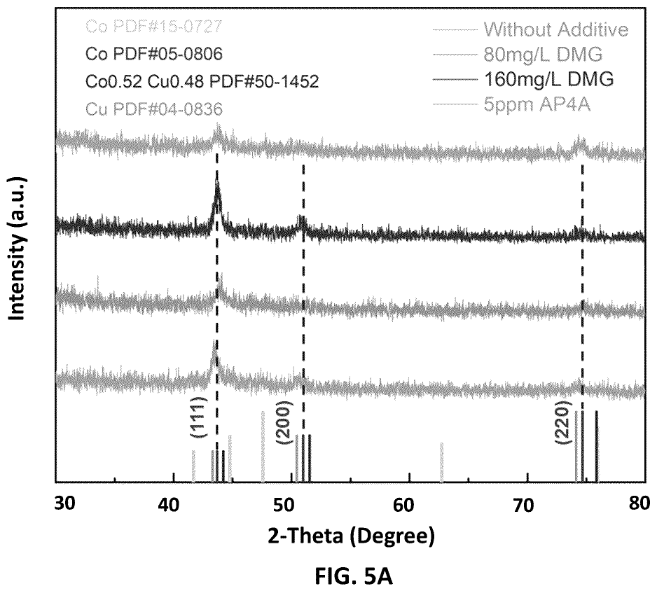

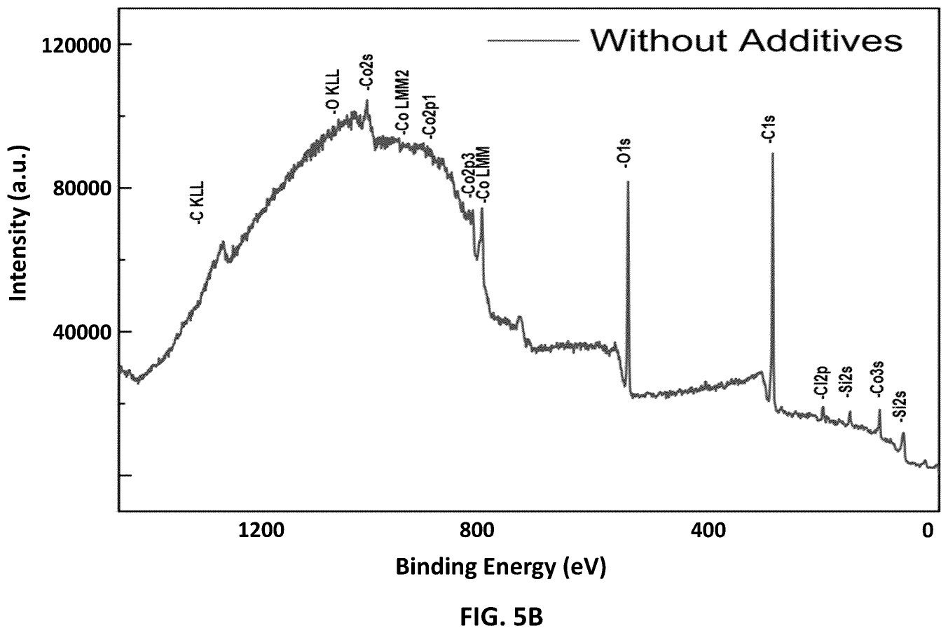

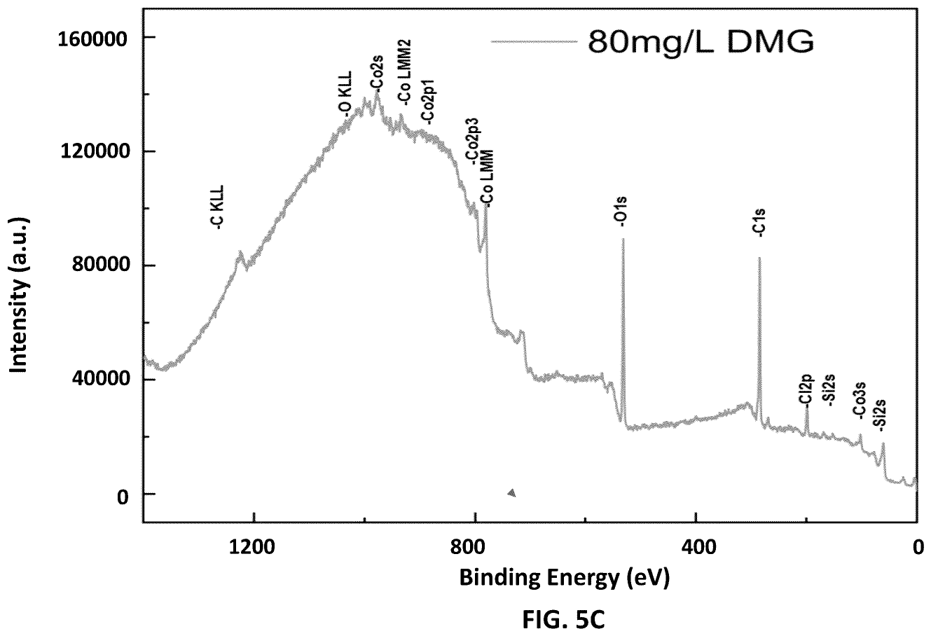

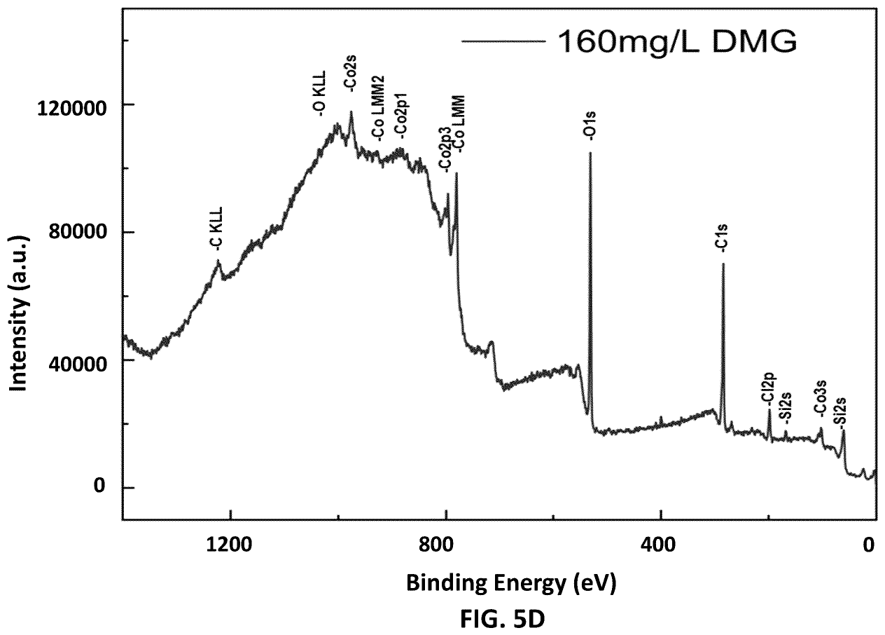

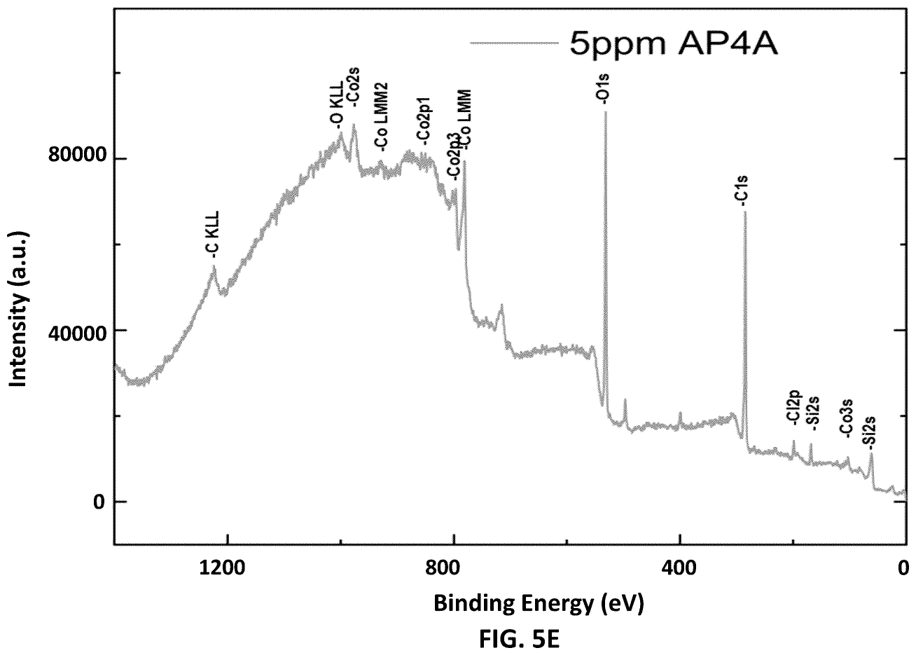

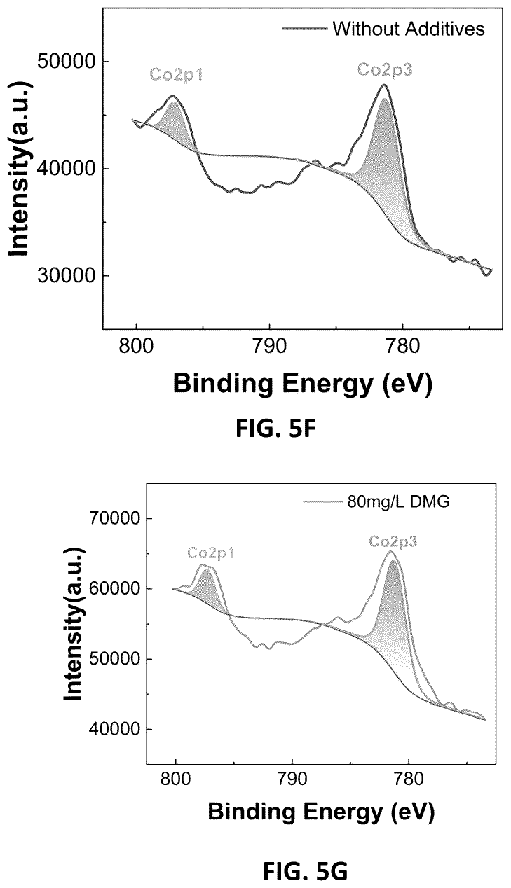

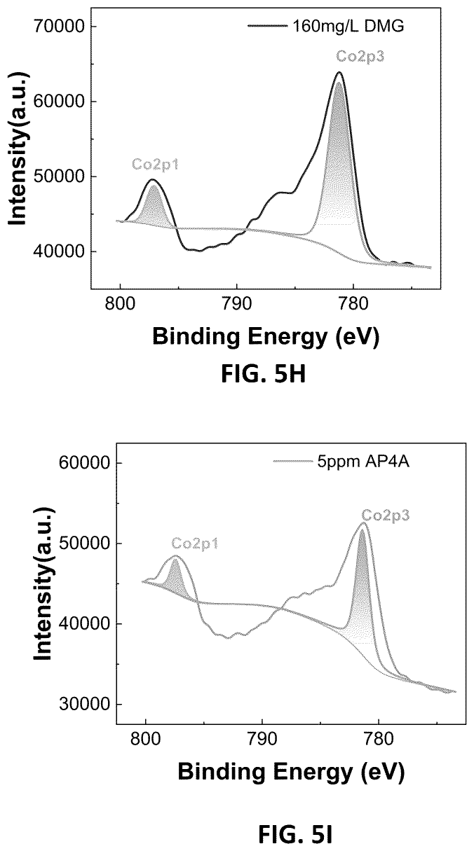

The impact of AP4A and DMG in cobalt electrodeposition was examined using a variety of characterizations. GIXRD was used to determine the physical phase of electroplated deposited cobalt films to avoid substrate interference. The test scans ranged from 30° to 80° with a scanning speed of 4°/min and a specified grazing incidence angle of 0.5°. The GIXRD results are shown in FIG. 5A, and the PDF card corresponding to cobalt plated using the cobalt sulfate electrolyte system of this work is cobalt PDF #15-0806, in the FCC structure. XRD studies reveal that DMG significantly affects the crystal structure of cobalt films. DMG limits the growth of cobalt (220) planes while promoting growth in the (111) and (200) planes.

The XPS survey results in FIGS. 5B to 5E and XPS high-resolution spectra images and fitted curves in FIGS. 5F to 5I reflect that the electrodeposited film contains cobalt elements, as well as other C, O, Cl, Si, and other impurity element peaks. Since the wafer substrate is not completely covered, Si is measured. The presence of components such as C and O is owing to the retention of the organic compounds AP4A or DMG on the surface. Hydrochloric acid was added during the preparation of the plating solution, which remained on the plating solution's surface after electrodeposition.

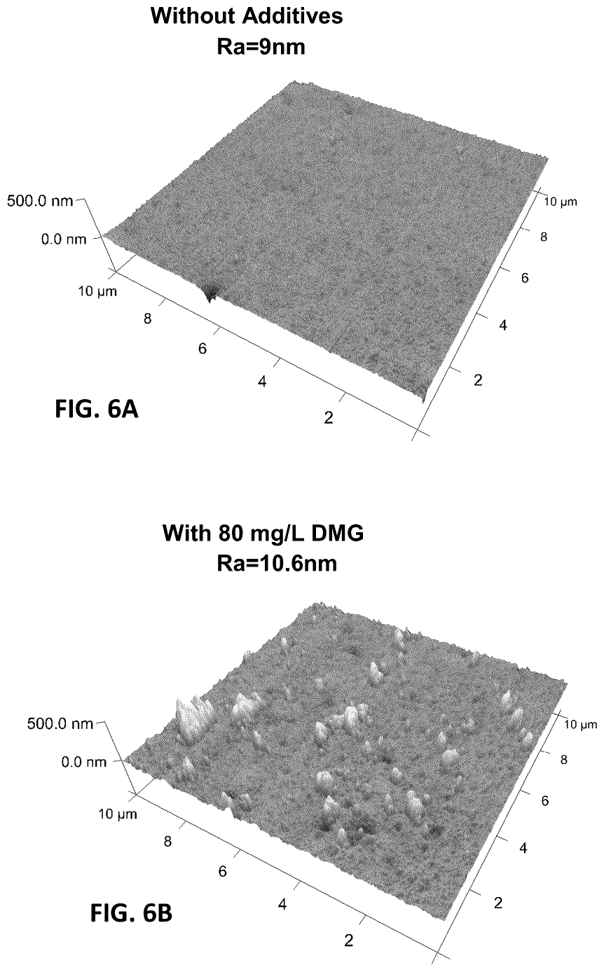

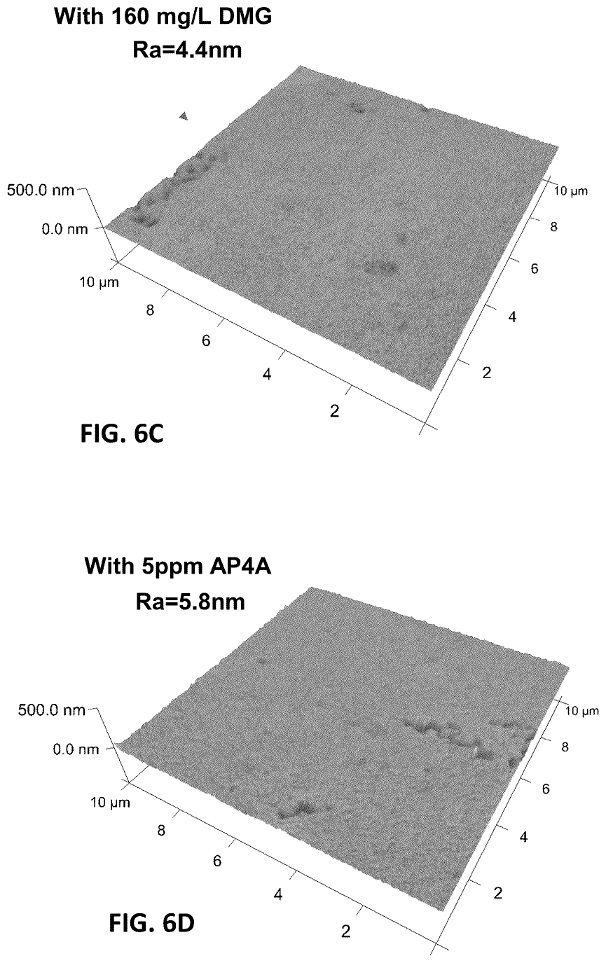

The surface roughness was measured by AFM, as shown in FIG. 6. The roughness (Ra) of the cobalt film deposited using the electrolyte without any additives was 9 nm, and the roughness (Ra) of the cobalt film deposited using the electrolyte with 160 mg/L DMG was 4.4 nm, which is the smoothest of all the samples tested. It also indicates that the surface roughness increases with the addition of DMG up to a certain value and then decreases with the increase in concentration.

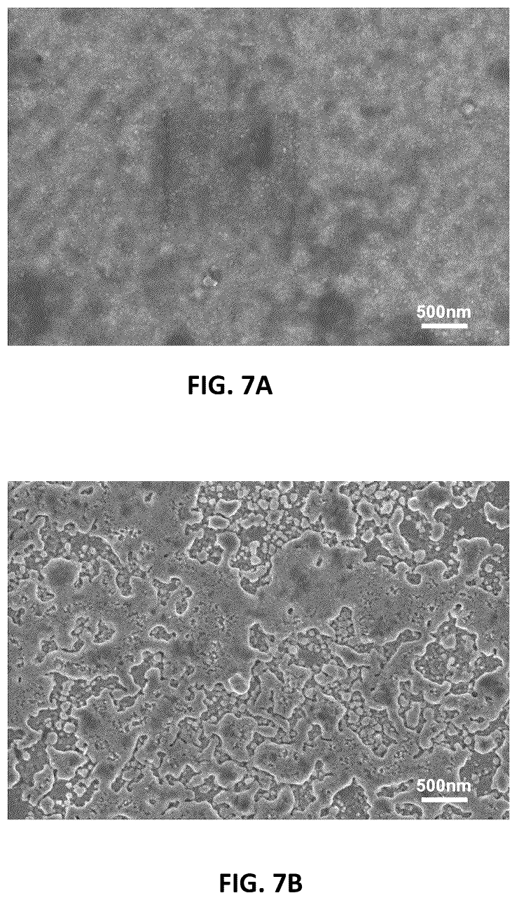

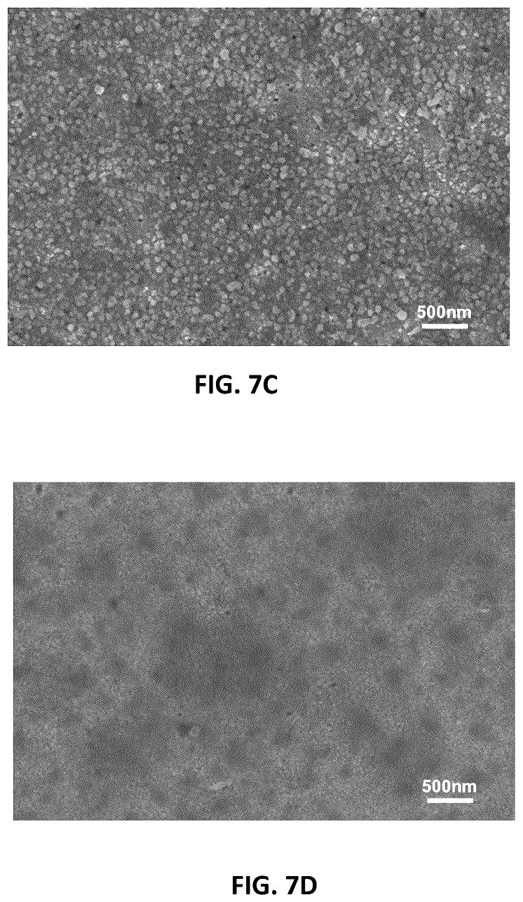

The SEM images (FIG. 7) illustrate the influence of additives on the surface morphology. Similar to the AFM results, when 80 mg/L DMG was added, the cobalt film surface was the flattest and densest, and the grains became larger. When the DMG addition amount was 80 mg/L, the grains showed uneven deposition. Because of the formation of grains when the metal atoms crystallize together to form the metal phase, the cobalt deposition rate in the plating solution is accelerated when the DMG concentration reaches 80 mg/L. Additionally, the plating layer creates internal stresses, causing the film to display outgrowths (hillocks).

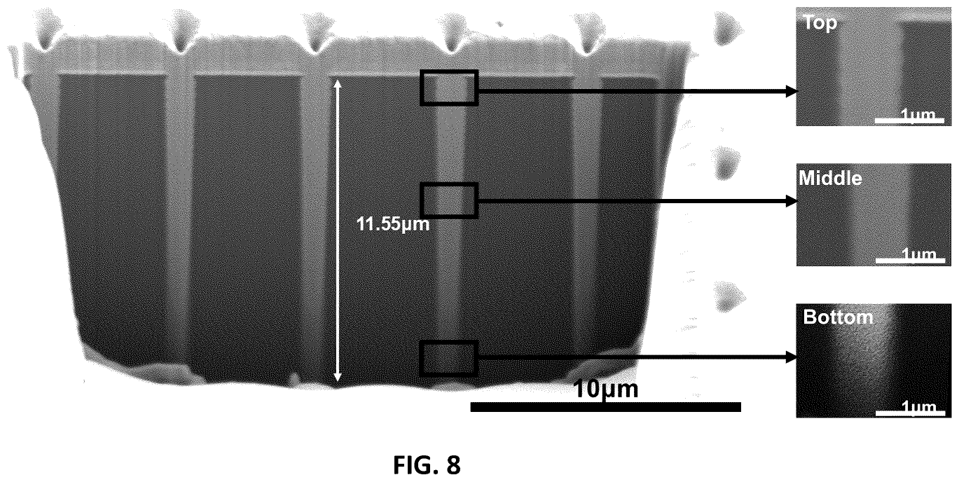

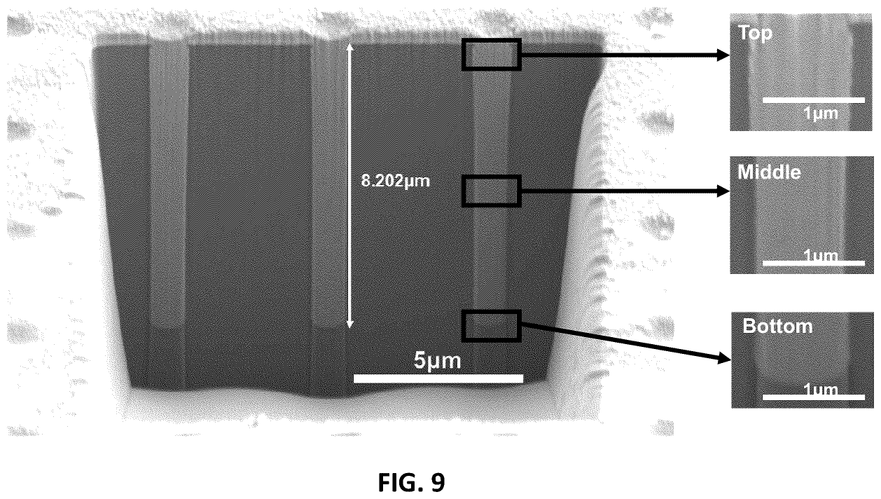

As shown in FIG. 8 and FIG. 9, compared to AP4A, adding DMG could achieve a deeper aspect ratio and have better filling. Insets in FIGS. 8 and 9 depict filled portions at the top, middle, and bottom of a single TSV from FIGS. 8 and 9, respectively. The magnified view of each area also reveals no voids or delamination within the TSV. The magnified view of each images of each location reveal no voids or delamination between the plated-filled cobalt within the TSV and the TSV wall.

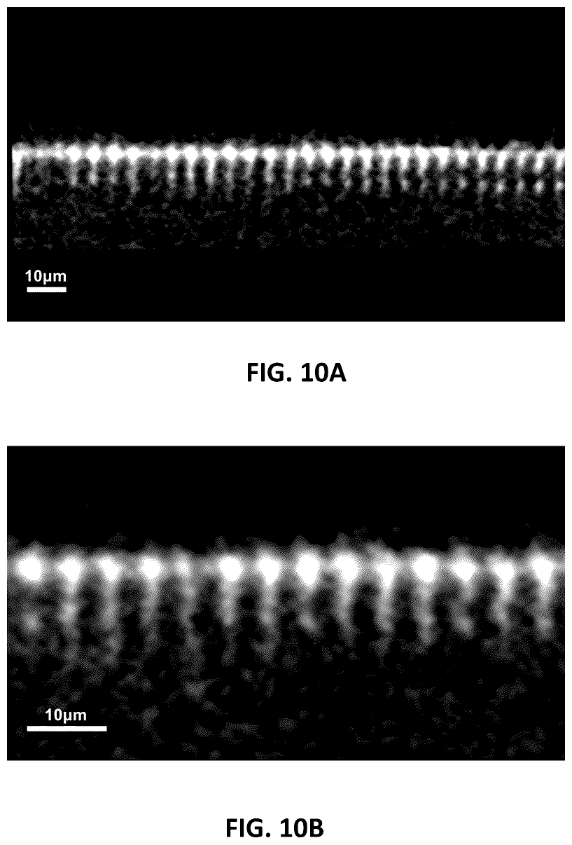

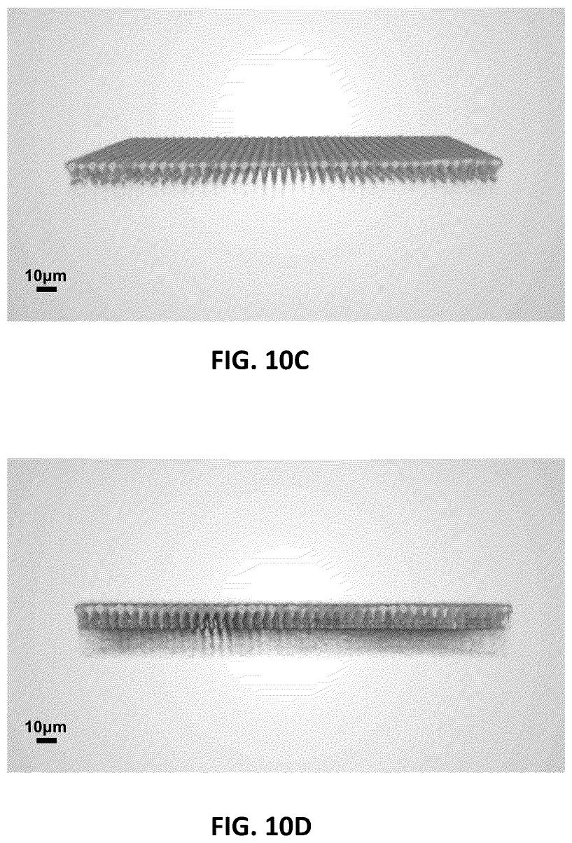

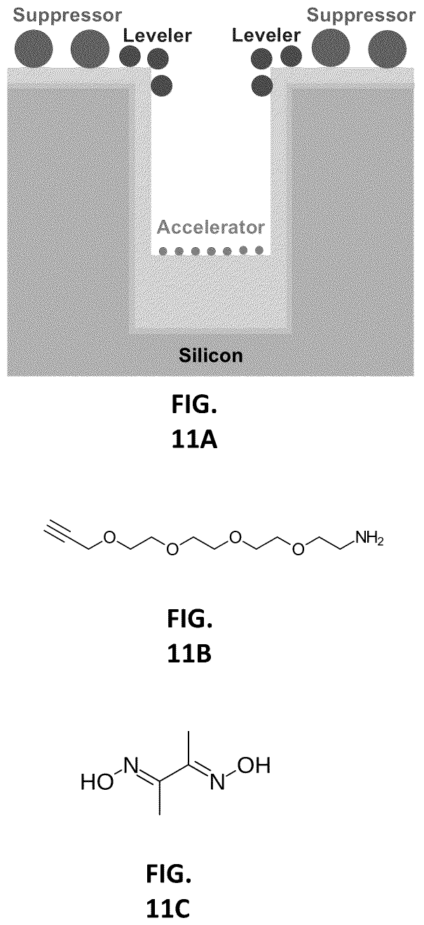

To effectively demonstrate the TSV filling effect on a larger scale, high-resolution X-ray CT was employed to visualize the filling across all TSVs on the wafer. The CT images shown in FIG. 10A to FIG. 10D reveal the larger scale of TSV filling results, TSV has been uniformly filled over a variety of regions.

### Mechanism of Cobalt Bottom-Up (Super) Filling

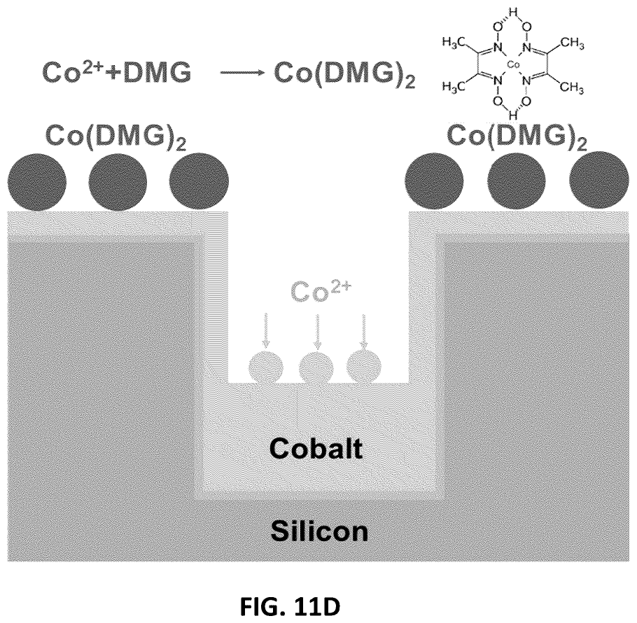

As shown in FIG. 11A, the additives classified as suppressor, leveler, and accelerator all have chemical properties that prevent electroplating. The accelerator and leveler exhibit a competitive adsorption relationship, but the suppressor and leveler have a synergistic impact on electroplating inhibition, particularly at high voltage and low suppressor concentration. The interaction investigations of additives in pairs reveal that the suppressor absorbed on the cathode surface is progressively displaced by the accelerator as its concentration rises. Additives that diminish deposition kinetics are often referred to as “suppressors” (or “inhibitors”), whereas adsorbates that augment the impact of inhibition are known as “accelerators”.

Based on some researches, a pair of amines (imine) groups should be responsible for the suppression action, while the mercapto group is for acceleration. The structural formulas of AP4A and DMG are displayed in FIG. 11B and FIG. 11C, respectively. The absence of mercapto groups and presence of amine groups in AP4A and DMG can act as suppressors within the bottom-up filling mechanism. Therefore, both AP4A and DMG have inhibitory effects on cobalt electrodeposition for filling small-sized TSVs. Since the selected additives AP4A and DMG both have pairs of amines (imine) groups, both have a good inhibition ability in cobalt electroplating filling.

The structure of DMG, particularly when complexed with Co2+ (Shown in FIG. 11D), only consists of two conjugated imine groups and no sulfur-containing compounds. When DMG is added, the plating solution undergoes the cobalt complexation reaction to form Co[DMG] 2 and the cobalt ion reduction reaction. As a surface adsorption intermediate step is necessary to reduce the Co[DMG]₂ complex, surface coated with [Co(DMG)₂] ads would react differently during Co deposition. Furthermore, the deposition of non-complexed Co (II) may include an adsorbed Co (I) intermediary species. Competitive adsorption of various species can reduce Co deposition. Although the bulk of Co (II) is present in the electrolyte in non-complexed form, suppression effect is introduced by the competition for the electrode surface caused by [Co(DMG)₂] ads.

In electrodeposition, AP4A molecules absorb into the electrode surface during the cobalt electrodeposition process, changing the distribution of current density and the intensity of the partial electric field, thereby exhibit a strong inhibitory effect on electrodeposition. Furthermore, mass transfer causes molecules to accumulate at the top of the hole, resulting in a stronger inhibitory impact and slower reduction of cobalt ions. The presence of AP4A molecules creates an electric field and concentration gradient, causing cobalt ions to deposit faster at the bottom of the hole than at the top. While the present disclosure has been described and illustrated with reference to specific embodiments, such descriptions and illustrations are not limiting and are to be regarded as illustrative rather than restrictive. The figures may not necessarily be drawn to scale, and differences between the illustrations and the actual apparatus may arise due to manufacturing processes and tolerances, including variations such as angled surfaces, rounded corners, or conformal deposition and etching effects. As used herein, and unless otherwise defined, the terms “substantially,” “substantial,” “approximately,” and “about” are intended to account for small variations. When applied to an event or circumstance, these terms encompass instances in which the event or circumstance occurs precisely as described as well as instances in which it occurs to a close approximation.

The embodiments have been described to explain the principles of the disclosure and its practical applications so that those skilled in the art can readily understand, implement, and adapt the disclosure for various embodiments and modifications suited to particular uses. Other embodiments not specifically illustrated may be realized, and modifications may be made to adapt a particular situation, material, composition of matter, method, or process to the objectives of the disclosure. All such modifications are intended to fall within the scope of the appended claims. The methods disclosed herein, although described with reference to particular operations performed in a particular order, are not limited to such order. Unless expressly indicated otherwise, the operations may be combined, subdivided, or re-ordered to form equivalent methods without departing from the teachings herein.

What is claimed is:

1. A method for filling cobalt into through vias of a semiconductor wafer, the method comprising:
preparing a cobalt-based electroplating solution;
performing wetting treatment on the through vias of the semiconductor wafer to obtain a wetting-treated wafer with wetting-treated through vias; and
filling cobalt into the wetting-treated through vias of the wetting-treated wafer by performing electroplating treatment with the prepared cobalt-based electroplating solution;
wherein the wetting treatment is performed by:
immersing the semiconductor wafer in an organic solvent to obtain an organic solvent-treated wafer;
immersing the semiconductor wafer in deionized water to obtain a deionized water-treated wafer; and
putting the deionized water-treated wafer in a vacuum container containing the prepared cobalt-based electroplating solution to obtain the wetting-treated wafer.

2. The method according to claim 1, the cobalt-based electroplating solution is prepared by:
dissolving and mixing a cobalt-based main salt and a stabilizer into deionized water to obtain a first solution;
dissolving a buffer into the first solution to obtain a second solution;
successively adding a grain refiner, a surfactant, a levelling agent and an inhibitor into the second solution to obtain a third solution;
fixing the third solution to a required amount with deionized water; and
adjusting the pH value of the third solution using an acid and/or alkaline to obtain the cobalt-based electroplating solution.

3. The method according to claim 2, wherein the cobalt-based main salt is a cobalt sulfate heptahydrate.

4. The method according to claim 3, wherein the stabilizer is a methanesulfonic acid, a sodium methanesulfonate, a citric acid, a sodium citrate, an ethylenediaminetetraacetic acid (EDTA) or any combinations thereof.

5. The method according to claim 4, wherein the buffer is a boric acid, a sodium borate, a phosphoric acid, a sodium phosphate, an acetic acid and a sodium acetate or any combinations thereof.

6. The method according to claim 5, wherein the grain refiner is a 1,3,5-naphthalene trisulfonic acid, a thiophene-2-sulfonic acid, a bis(phenylsulfonyl)imide, a N-propenylpyridinium chloride or any combinations thereof.

7. The method according to claim 6, wherein the surfactant is a dipentyl sulfosuccinate sodium salt, a sodium polyoxyethylene alkyl phenol ether sulfate, and a lauryl ether sulfate or any combinations thereof.

8. The method according to claim 7, wherein the levelling agent is a dimethylglyoxime.

9. The method according to claim 8, wherein the inhibitor is a mercaptobenzimidazole sulfonic acid, a polyethyleneimine, a thiourea, a butanedione oxime, a 2-mercaptobenzimidazole benzenesulfinic acid, and an alkynyl-PEG4-amine or any combinations thereof.

10. The method according to claim 9, wherein
the stabilizer is a sodium citrate; the buffer is a sodium borate; the grain refiner is a 1,3,5-naphthalene trisulfonic acid; the surfactant is a sodium polyoxyethylene alkyl phenol ether sulfate; the inhibitor is a butanedione oxime;
the sodium citrate and the cobalt sulfate heptahydrate have a weight ratio equal to 3:8;
the sodium borate and the cobalt sulfate heptahydrate have a weight ratio equal to 5:16;
the 1,3,5-naphthalene trisulfonic acid and the cobalt sulfate heptahydrate have a weight ratio equal to 1:800;
the sodium polyoxyethylene alkyl phenol ether sulfate and the cobalt sulfate heptahydrate have a weight ratio equal to 1:200;
the dimethylglyoxime and the cobalt sulfate heptahydrate have a weight ratio equal to 1:320; and
the butanedione oxime and the cobalt sulfate heptahydrate have a weight ratio equal to 3:800.
